(19) United States
(12) Patent Application Publication
(10) Pub. No.: US 2026/0045453 A1
(43) Pub. Date: Feb. 12, 2026

(54) SUBSTRATE PROCESSING APPARATUS

(71) Applicant: Samsung Electronics Co., Ltd., Suwon-si (KR)

(72) Inventors: Sangjine PARK, Suwon-si (KR); Ji Hwan PARK, Suwon-si (KR)

(21) Appl. No.: 19/050,789

(22) Filed: Feb. 11, 2025

(30) Foreign Application Priority Data
Aug. 12, 2024 (KR) 10-2024-0107657

(51) Int. Cl. H01J 37/32; H01L 21/3065

(52) U.S. Cl. CPC H01J 37/32522; H01J 37/32449; H01J 37/32724; H01J 2237/002; H01J 2237/20214; H01J 2237/334; H01L 21/3065

(57) ABSTRACT

Provided is a substrate processing apparatus, including a chamber including a plasma region and a processing region configured to process a substrate, a gas supply configured to supply a plasma gas to the plasma region and supply an etching gas to the processing region, a power supply configured to generate a plasma from the plasma gas, a blocker disposed between the plasma region and the processing region and configured to selectively allows radicals in the plasma to pass from the plasma region to the processing region, a shower head including a gas flow path configured to supply the etching gas to the processing region and a radical flow path configured to supply the radicals to the processing region, and a heater configured to adjust a temperature of the etching gas moving along the gas flow path or a temperature of the radicals moving along the radical flow path.

### CROSS-REFERENCE TO RELATED APPLICATION

This application claims priority under 35 U.S.C. § 119 to Korean Patent Application No. 10-2024-0107657, filed in the Korean Intellectual Property Office on Aug. 12, 2024, the entire contents of which are hereby incorporated by reference.

### BACKGROUND

### Field

The present disclosure relates to a substrate processing apparatus.

### Description of Related Art

Manufacturing processes of semiconductor devices may be performed through substrate processing apparatus each performing deposition, etching, or cleaning process. Damage may occur on a surface of a semiconductor device during the etching process, and it is necessary to repair it to ensure the performance of the semiconductor device.

As a method for repairing the surface damage of the semiconductor device, hydrogen plasma anneal (HPA) using hydrogen plasma may be used. This method involves injecting hydrogen gas into a vacuum chamber and forming plasma by transforming hydrogens into hydrogen radicals to make silicon atoms on the surface of the semiconductor device move to repair the damage.

### SUMMARY

In order to solve one or more problems (e.g., the problems described above and/or other problems not explicitly described herein), embodiments of the present disclosure provide a substrate processing apparatus capable of manufacturing a semiconductor device having improved electrical performance.

Embodiments of the present disclosure also provide a substrate processing apparatus that performs an etching process and an annealing process together in a single chamber.

Embodiments of the present disclosure also provide a substrate processing apparatus that improves temperature uniformity of a substrate in an etching process and in an annealing process.

According to some example embodiments of the present disclosure, a substrate processing apparatus may include a chamber including a plasma region and a processing region configured to process a substrate, a gas supply configured to supply a plasma gas to the plasma region and supply an etching gas to the processing region, a power supply configured to generate a plasma from the plasma gas, a blocker disposed between the plasma region and the processing region and configured to selectively allow radicals in the plasma to pass from the plasma region to the processing region through the blocker, a shower head including a gas flow path configured to supply the etching gas to the processing region and a radical flow path configured to supply the radicals to the processing region, and a heater configured to adjust a temperature of the etching gas moving along the gas flow path or a temperature of the radicals moving along the radical flow path.

According to some example embodiments, a substrate processing apparatus may include a chamber including a plasma region configured such that a plasma ions and radicals is formed in the plasma region, and a processing region configured such that a substrate is processed in the processing region, a blocker disposed between the plasma region and the processing region, the blocker configured to allow the radicals to pass from the plasma region to the processing region through the blocker and block the ions, a shower head including a first gas flow path configured to supply an etching gas to a first region of the substrate, a second gas flow path configured to supply an etching gas to a second region surrounding the first region of the substrate, and a radical flow path configured to supply the radicals passed through the blocker to the substrate, a first heater connected to the first gas flow path, and a second heater connected to the second gas flow path, in which the first heater and the second heater may be separated from each other with the radical flow path therebetween.

According to some example embodiments, a substrate processing apparatus may include a chamber including a plasma region configured such that a plasma including hydrogen ions and hydrogen radicals is formed in the plasma region, and a processing region configured to process a substrate, a gas supply configured to supply a hydrogen gas to the plasma region and supply an etching gas to the processing region, a power supply disposed above the chamber and generating a plasma from the hydrogen gas, a blocker disposed inside the chamber to separate the plasma region and the processing region, in which the blocker may allow the hydrogen radicals to pass through to the processing region and may block the hydrogen ions, and a substrate support configured to support the substrate in the processing region and including a heater channel and a cooling channel therein, and the substrate is rotatably drivable, a shower head including a first gas flow path for supplying an etching gas to a first region of the substrate, a second gas flow path configured to supply the etching gas to a second region surrounding the first region of the substrate, and a radical flow path configured to supply the hydrogen radicals passed through the blocker to the substrate, a first heater connected to the first gas flow path, and a second heater connected to the second gas flow path and surrounding the first heater, in which the radical flow path may be formed between the first heater and the second heater, and the first heater and the second heater may be configured to be operated independently of each other and configured such that a temperature set by the first heater may be lower than a temperature set by the second heater.

According to some example embodiments, the substrate processing apparatus may improve the surface quality of the semiconductor device, thereby improving electrical performance of the semiconductor device.

According to some example embodiments, the substrate processing apparatus may perform both the etching process and the annealing process in a single chamber.

According to some example embodiments, the substrate processing apparatus includes a heater that adjusts the temperature for each region of the substrate to ensure temperature uniformity for each region of the substrate during the substrate processing process.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIG. 1 is a schematic diagram illustrating a substrate processing apparatus according to some example embodiments;

FIG. 2 is a cross-sectional view schematically illustrating a substrate processing apparatus according to some example embodiments;

FIG. 3 is a diagram illustrating the substrate processing apparatus of FIG. 2 from a different angle;

FIG. 4 is a diagram provided to explain various region of a substrate;

FIG. 5 is a cross-sectional view illustrating a main configuration of a substrate processing apparatus according to some example embodiments;

FIG. 6 is a cross-sectional view illustrating a partial configuration of the substrate processing apparatus of FIG. 5;

FIG. 7 is an enlarged view of the region A of FIG. 6;

FIG. 8 is a diagram provided to explain an etching process in a substrate processing apparatus according to some example embodiments;

FIG. 9 is a cross-sectional view of a semiconductor structure manufactured using a substrate processing apparatus according to some example embodiments;

FIG. 10 is a diagram provided to explain an annealing process in a substrate processing apparatus according to some example embodiments;

FIG. 11 is an enlarged cross-sectional view of the region B of the substrate processing apparatus of FIG. 10;

FIGS. 12 and 13 are conceptual diagrams illustrating a portion of the semiconductor structure of FIG. 9; and

FIG. 14 is a flowchart illustrating a substrate processing method according to some example embodiments.

### DETAILED DESCRIPTION

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Hereinafter, a substrate processing apparatus according to some example embodiments will be described in detail with reference to the drawings.

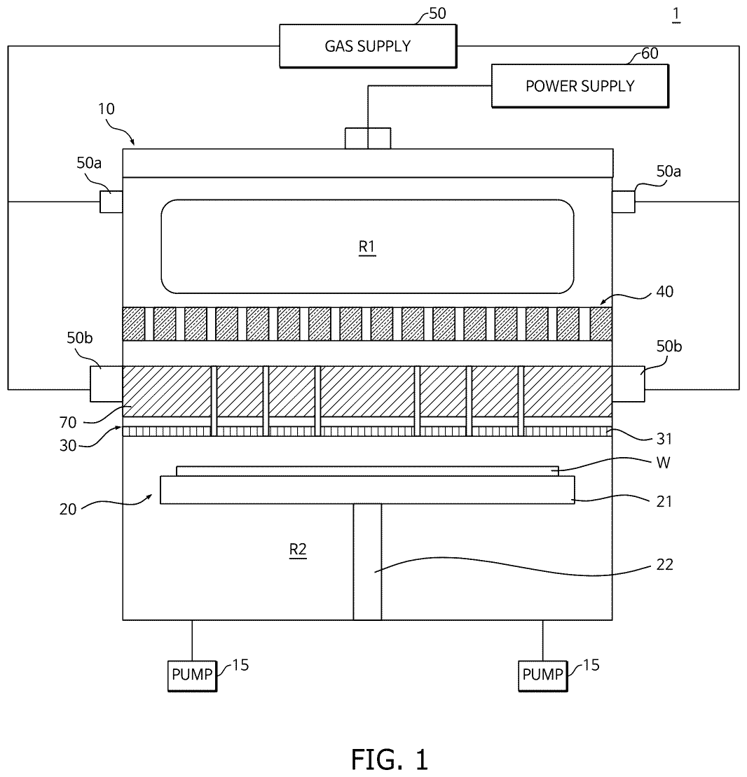

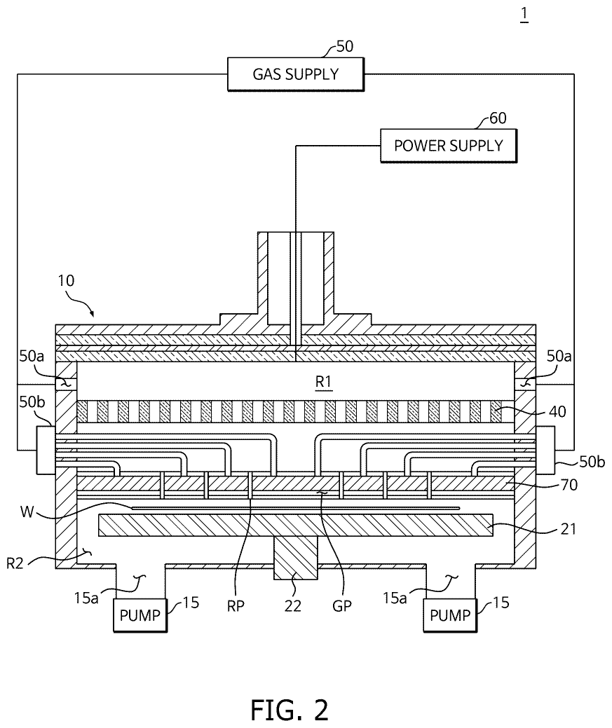

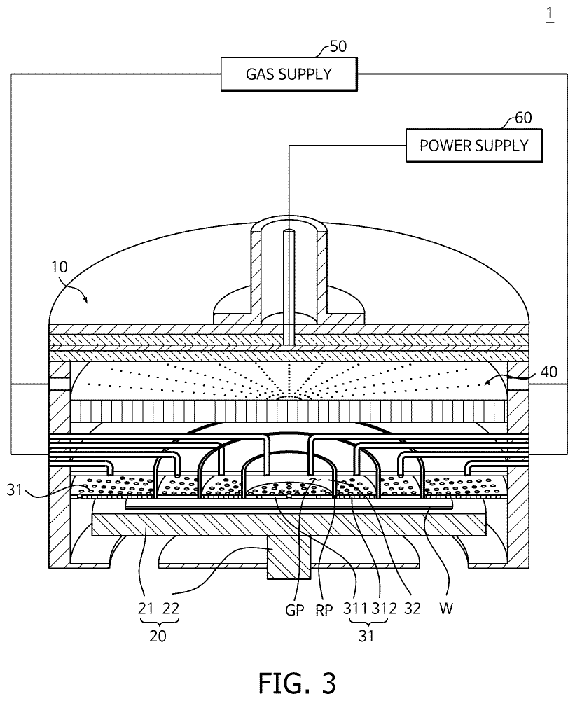

FIG. 1 is a schematic diagram illustrating a substrate processing apparatus according to some example embodiments. FIG. 2 is a cross-sectional view schematically illustrating a substrate processing apparatus according to some example embodiments. FIG. 3 is a diagram illustrating the substrate processing apparatus of FIG. 2 from a different angle.

Referring to FIGS. 1 to 3, a substrate processing apparatus 1 according to some example embodiments may include a chamber 10, a substrate support 20, a shower head 30, a blocker 40, a gas supply 50, a power supply 60, a heater 70, etc.

The substrate processing apparatus 1 may be a dry cleaning device that performs etching cleaning on the substrate W provided on the substrate support 20. Alternatively, the substrate processing apparatus 1 may be a dry etching apparatus that performs an etching process using plasma. The substrate W may be a silicon wafer used for manufacturing a semiconductor device. As used herein, a semiconductor device may refer to any of the various devices such as two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages.

The substrate processing apparatus 1 may form plasma by an inductively coupled plasma (ICP) method and/or a capacitively coupled plasma (CCP) method, but the method of forming plasma of the substrate processing apparatus 1 is not limited thereto.

The chamber 10 may provide a space in which plasma is formed and a space in which substrate processing is performed. The chamber 10 may provide a sealed inner space in which the substrate W is processed. The chamber 10 may be provided with a passage (not illustrated) on one side through which the substrate W is carried in and out. The chamber 10 may be formed of a metallic material, and may include, for example, aluminum (Al) or an alloy thereof.

The chamber 10 may include a plasma region R1 in which plasma is formed, and a processing region R2 in which substrate processing is performed. Plasma may be formed in the plasma region R1 so that ions and radicals may be present in the plasma region R1. The processing region R2 may be a region for processing the substrate W. The plasma region R1 and the processing region R2 may be separated by the blocker 40. The plasma region R1 may be positioned in an upper portion of the chamber 10, and the processing region R2 may be positioned in a lower portion of the chamber 10, but the inventive concept of the present application is not limited thereto.

The interior of the chamber 10 may be formed of an insulating material to prevent damage from plasma and/or generation of particles. For example, the interior of the chamber 10 may include quartz, Al₂O₃, AlN, Y₂O₃, etc.

An exhaust port 15a may be formed at a portion of the chamber 10. The exhaust port 15a may be formed on a bottom of the chamber 10. The air/gas inside the chamber 10 may be discharged through the exhaust port 15a. A plurality of exhaust ports 15a may be formed on the bottom of the chamber 10. The number of the exhaust ports 15a may be arbitrarily set, and may be formed/arranged in a circumferential direction of the bottom surface of the chamber, e.g., surrounding a central axis of the chamber 10 extending in a vertical direction, and may be disposed in a concentric shape/arrangement.

A pump 15 may be disposed under the chamber 10. The pump 15 may be connected to the exhaust port 15a to discharge the gas from the inside of the chamber 10 to the outside of the chamber 10. The pump 15 may be configured to adjust the pressure within the chamber 10 to depressurize the atmosphere in the chamber 10 to a predetermined degree of vacuum. For example, the pressure in the plasma region R1 may be about 10 mTorr to about 150 mTorr, but is not limited thereto. The pump 15 may discharge the gas from the inside of the chamber 10 to the outside to maintain the inside of the chamber 10 in a vacuum state. For example, the pump 15 may be a vacuum pump. A control unit (e.g., a controller, not illustrated) may control the pump 15 to adjust the pressure state in the chamber 10.

The substrate support 20 may be disposed in the processing region R2. The substrate support 20 may support the substrate W while the processing of the substrate W is performed. For example, the substrate support 20 may include a hot/thermal chuck, an electrostatic chuck (ESC), a heater, and/or a susceptor. For example, the substrate support 20 may be configured to vacuum-adsorb (adsorb the substrate W with a low pressure) and support the substrate W by a hot/thermal chuck.

The substrate support 20 may include a pedestal 21 that supports the substrate W and a drive shaft 22 vertically extending (e.g., lengthwise) and connected to the pedestal 21 such that the drive shaft 22 extends in a perpendicular direction from the pedestal 21 extending in a horizontal direction. The substrate W may be seated on an upper surface of the pedestal 21. The drive shaft 22 may be connected to a bottom surface of the pedestal 21. The pedestal 21 may be rotated about the drive shaft 22 as an axis of rotation. For example, a central axis of the drive shaft 22 may be the axis of rotation of the pedestal 21. The drive shaft 22 may be coupled to a driving device (not illustrated). The driving device may include a driving motor, etc. that generates a rotational force. In some example embodiments, the substrate support 20 may be configured to rise and descend/fall, or may include an elevating pin for raising and lowering the substrate W. The substrate support 20 may include a heater channel and a cooling channel for adjusting the temperature of the substrate W. The substrate support 20 may adjust the temperature of the substrate W by heating or cooling the substrate support 20 and/or the substrate W.

The shower head 30 may be disposed to be spaced apart from an upper side/surface of the substrate support 20. For example, the shower head 30 may be positioned above the top surface of the substrate support 20. The substrate W may be positioned on the upper surface of the substrate support 20. For example, the substrate W may be disposed between the substrate support 20 and the shower head 30.

The shower head 30 may be disposed in the processing region R2. The shower head 30 may inject an etching gas supplied from the gas supply 50 to the substrate W. The shower head 30 may introduce or inject radicals present in the plasma region R1 onto the substrate W. For example, the shower head 30 may supply the etching gas toward the substrate W seated on the substrate support 20. The etching gas supplied through the shower head 30 may etch a portion of the substrate W. The shower head 30 may supply the radicals toward the substrate W seated on the substrate support 20. The radicals supplied through the shower head 30 may treat the surface of the substrate W.

The shower head 30 may include a gas flow path GP for supplying the etching gas to the processing region R2 and a radical flow path RP for supplying the radicals to the processing region R2. For example, the etching gas may be supplied to the shower head 30 and to the substrate W through the gas flow path GP, and the radicals may be supplied to the shower head 30 and to the substrate W through the radical flow path RP. In certain embodiments, the shower head 30 may include a part of a gas flow path GP and a part of a radical flow path RP. For example, FIG. 2 shows that a part of each of a plurality of radical flow paths RP is formed in a shower head 30 and each of the plurality of radical flow paths RP is passing through a heater 70 and the shower head 30. The gas flow path GP and the radical flow path RP may be flow paths independent of each other. The gas flow path GP and the radical flow path RP may be physically separated/divided and may be spaced apart from each other. The shower head 30 may include a gas injection unit 31. The gas injection unit 31 may be disposed downstream of the shower head 30. For example, the gas injection unit 31 may be positioned at a lower part of the shower head 30. A plurality of injection holes for injecting gas may be formed in the gas injection unit 31. For example, the shower head 30 may include the plurality of injection holes.

The shower head 30 may include a partition structure 32 penetrating the gas injection unit 31. The partition structure 32 may separate the gas injection unit 31 into a plurality of areas. For example, the partition structure 32 may divide the gas injection unit 31 into a first gas injection unit 311 positioned in the center and a second gas injection unit 312 disposed outside the first gas injection unit 311. For example, each of the first and second gas injection units 311 and 312 may be a part of the gas injection unit 31. In certain embodiments, the shower head 30 may include a plurality of gas injection units in which case each of the first and second gas injection units 311 and 312 may be one of the plurality of gas injection units 31. The gas injection units 31 may be a plate having injection holes in it and may be positioned at a bottom of the shower head 30. For example, each of the first and second gas injection units 311 and 312 may be a plate having injection holes in it and may be positioned at a bottom of the shower head 30. For example, the partition structure 32 may be disposed between the first gas injection unit 311 and the second gas injection unit 312. For example, the first gas injection unit 311 may be a first part of the shower head 30 and include a plurality of injection holes in the first part, and the second gas injection unit 312 may be a second part of the shower head 30 and include a plurality of injection holes in the second part. The partition structure 32 in the present disclosure may be a partition, and may be a space between two elements (e.g., gas injection units, gas flow paths, and/or heaters) and/or may include an insulation material, e.g., in a form of a plate, etc., interposed between the two elements.

The heater 70 may adjust the temperature of the etching gas moving along the gas flow path GP or the temperature of the radicals moving along the radical flow path RP. For example, the gas flow path GP may pass through the heater 70 and through the shower head 30, and the radical flow path RP may pass through the heater 70 and through the shower head 30. The heater 70 may adjust the temperature of the etching gas and the radicals before the shower head 30 injects the etching gas and the radicals. For example, the heater 70 may be disposed upstream of the shower head 30, e.g., in terms of flowing directions of the radicals and/or the etching gas. For example, the heater 70 may be disposed above the shower head 30. The heater 70 may maintain the temperature of the etching gas at approximately −30° C. to 200° C., but the inventive concept is not limited thereto. In addition, the heater 70 may maintain the temperature of the radicals at approximately 450° C. to 550° C., but the inventive concept is not limited thereto.

The heater 70 may be integrally formed with the shower head 30 or disposed separately from the shower head 30. In some example embodiments, the heater 70 may also be positioned inside the shower head 30. The heater 70 may be connected to the gas flow path GP of the shower head 30. The heater 70 may form a portion of the gas flow path GP. For example, the heater 70 may form a sidewall of the gas flow path GP. In certain embodiments, a portion of the gas flow path GP may be formed in the heater 70. The heater 70 may be concentric with respect to the center of the shower head 30. For example, the heater 70 may be formed of a plurality of parts, and the plurality of parts of the heater 70 may be arranged to be concentric, e.g., in a plan view. The heater 70 may be disposed upstream of the shower head 30, e.g., in terms of the flow direction of the etching/carrier gas, such that, after the temperature of the etching/carrier gas is adjusted by the heater 70, the etching/carrier gas with the adjusted temperature is injected through the shower head 30.

The blocker 40 may be disposed inside the chamber 10. The blocker 40 may divide the chamber 10 into the plasma region R1 and the processing region R2. In some example embodiments, the plasma region R1 may be disposed above the blocker 40, and the processing region R2 may be disposed below the blocker 40. The blocker 40 may be disposed between the plasma region R1 and the processing region R2. The blocker 40 may have a disk shape. For example, the chamber 10 may have a cylindrical shape and the disk shaped blocker 40 may be disposed in a middle portion of the chamber 10. The plasma region R1 and the processing region R2 may be communicated through a plurality of holes formed in the blocker 40. For example, the radicals of the plasma region R1 may move through the blocker 40. For example, the blocker 40 may be a plate having a plurality of holes extending through the plate from a bottom surface to a top surface of the plate.

The gas supply 50 may supply plasma gas required for the plasma generation. For example, the plasma gas may include hydrogen (H₂), duterium (D₂), etc. The gas supply 50 may supply the plasma gas to the plasma region R1 and supply the etching gas to the processing region R2. The gas required for the substrate processing, such as plasma gas (e.g., hydrogen), carrier gas, etching gas, etc. may be stored in the gas supply 50. When necessary, the gas supply 50 may further store inert gases such as helium, neon, argon, and/or nitrogen-based processing gases such as nitrogen, ammonia, hydrazine, etc.

The gas supply 50 may include a first gas supply pipe 50a and a second gas supply pipe 50b communicating with the interior of the chamber 10. The first gas supply pipe 50a may communicate with the plasma region R1 to supply the plasma gas. The second gas supply pipe 50b may communicate with the processing region R2 to supply the etching gas, etc.

The power supply 60 may generate plasma from the plasma gas. The power supply 60 may supply power required for the plasma generation. For example, the power supply 60 may apply radio frequency (RF) power in the form of electromagnetic waves with a predetermined frequency and intensity. The power supply 60 may generate a predetermined frequency, for example, a microwave of 2.45 GHz. The power supply 60 may apply a power of about 2000 W or more to the chamber 10. Power of about 3000 W to about 3500 W may also be applied to the chamber by the power supply 60.

Configurations of the substrate processing apparatus 1 processing the substrate W according to some example embodiments and a substrate processing process will be described below.

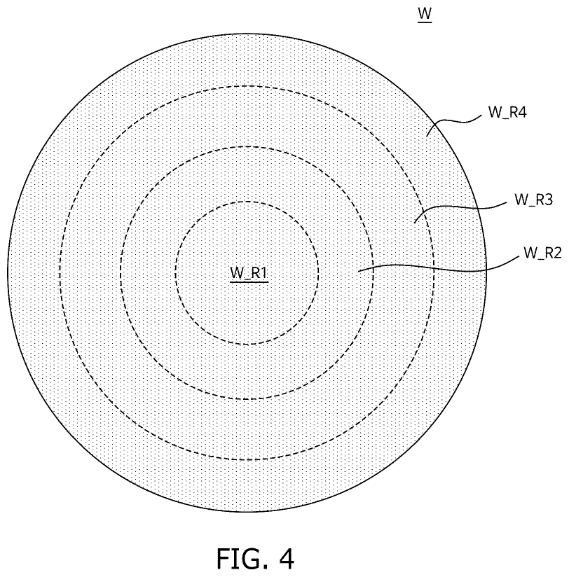

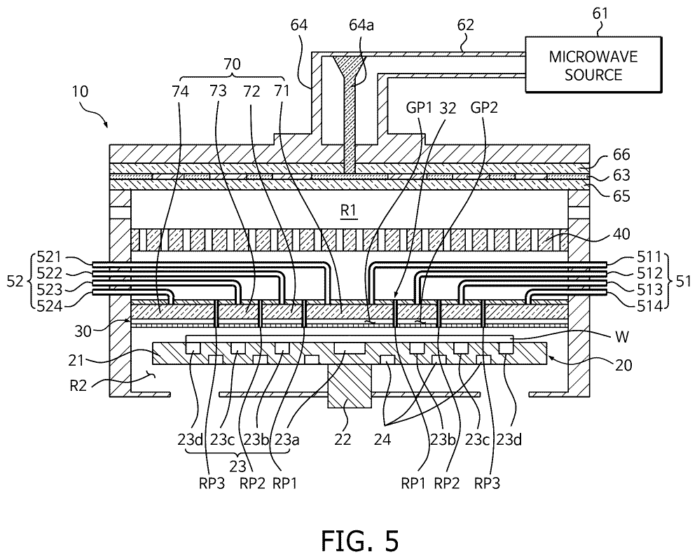

FIG. 4 is a diagram provided to explain various region of the substrate. FIG. 5 is a cross-sectional view illustrating a main configuration of the substrate processing apparatus according to some example embodiments.

Referring to FIG. 4, the substrate W may include a plurality of regions divided with respect to the center of the substrate W. The plurality of regions may be formed concentrically with respect to the substrate W. For example, the plurality of regions of the substrate W may be concentric ring shaped or disc shaped regions.

The substrate W may include first to fourth regions W_R1, W_R2, W_R3, and W_R4. The first region W_R1 may be a region including a center of the substrate W. The second region W_R2 may surround the first region W_R1 and may be positioned farther from the center of the substrate W than the first region W_R1. The third region W_R3 may surround the second region W_R2 and may be positioned farther from the center of the substrate W than the second region W_R2, and the fourth region W_R4 may surround the third region W_R3 and may be positioned farther from the center of the substrate W than the third region W_R3. The first region W_R1 may have a disk shape, and each of the second to fourth regions W_R2, W_R3, and W_R4 may have a ring shape. However, the shapes of the first to fourth regions W_R1, W_R2, W_R3, and W_R4 illustrated herein are only examples, and the inventive concept is not limited thereto.

In some example embodiments, the substrate W may be divided into three regions such as a center region, a middle region, and an edge region. In another aspect, the substrate W may be divided into two regions. Alternatively, the substrate W may include a plurality of divided regions divided in a grid pattern, e.g., in a plan view. In this case, the shapes and areas of the plurality of divided regions may be variously configured in consideration of the shape of the substrate W or the warpage of the substrate W. For convenience of description, the first region W_R1 and the second region W_R2 of the substrate W will be mainly described.

Referring to FIGS. 4 and 5, the substrate processing apparatus 1 according to some example embodiments may perform an etching process and an annealing process on the substrate W in one chamber 10. Both the etching process and the annealing process may be performed in the processing region R2 of the substrate processing apparatus 1. For example, the annealing process may be performed according to the hydrogen plasma anneal (HPA) method. The substrate processing apparatus 1 may be provided with the power supply 60 to generate plasma from hydrogen gas.

The power supply may include a microwave source 61 that generates microwaves, a tube waveguide 62, an antenna 63, a coaxial waveguide 64, a window plate 65, and a slow-wave plate 66. The power supply 60 may be disposed above the chamber 10, but the inventive concept is not limited thereto.

The microwave source 61 may generate a microwave with a frequency of approximately 2.45 MHz, but the inventive concept is not limited thereto. The microwave may be transmitted to the antenna 63 through the tube waveguide 62 and the coaxial waveguide 64. The tube waveguide 62 may have a tubular shape with a rectangular or elliptical cross-section. An inner surface of the tube waveguide 62 may be formed of a conductive material. A plurality of slits may be formed in the antenna 63, and the plurality of slits may be formed in various ways. For example, the plurality of slits may be disposed concentrically with respect to a center of the antenna 63. The antenna 63 may include a conductive material such as copper (Cu), aluminum (Al), nickel (Ni), etc. A power feeder 64a may be disposed in the coaxial waveguide 64. The power feeder 64a may transfer the high-frequency power to the antenna 63. The power feeder 64a may be connected to the antenna 63.

The window plate 65 may include a dielectric material such as quartz, Al₂O₃, AlN, etc. to facilitate the transmission of the microwaves. The slow-wave plate 66 may be provided on an upper portion of the antenna 63 and may serve to shorten the wavelength of the microwaves.

The slow-wave plate 66 may include a dielectric material such as quartz, Al₂O₃, AlN, etc. The window plate 65 may be disposed below the antenna 63, and the slow-wave plate 66 may be disposed above the antenna 63.

The plasma gas supplied from the gas supply 50 to the plasma region R1 may be converted into plasma by the high-frequency power applied from the power supply 60. A magnetic field may be generated around the antenna 63 by the current flowing through the antenna 63, and magnetic lines may penetrate the window plate 65, so that an induced electric field may be formed in the plasma region R1. Electrons accelerated by the induced electric field may collide with molecules or atoms of the plasma gas to generate plasma. In this way, microwaves generated by the microwave source 61 may pass through the window plate 65 and radiate into the plasma region R1, and plasma may be generated from plasma gas. In some example embodiments, the plasma may include hydrogen ions (H⁺), hydrogen radicals (H*), etc. The hydrogen radicals of the plasma may be used for processing the substrate W.

The shower head 30 may supply the etching gas toward the substrate W and supply the radicals introduced from the plasma region R1 to the substrate for the annealing process. For example, the radicals for the annealing process are supplied in a high-temperature environment, which may increase the temperature of the substrate W.

When heating the substrate W, a temperature difference may be formed between regions of the substrate W. For example, the first region W_R1 of the substrate W may have a higher temperature than the second region W_R2. If the temperature difference is formed on the substrate W, warpage of the substrate W may occur or process/pattern uniformity may be deteriorated.

The substrate processing apparatus 1 according to some example embodiments may supply the etching gas and the radicals with different temperatures for different regions of the substrate W to compensate different temperatures between different regions of the substrate W so as to improve the process uniformity of the substrate W. The heater 70 may be disposed adjacent to each region of the substrate W. The heater 70 may include a first heater 71 disposed adjacent to the first region W_R1 and a second heater 72 disposed adjacent to the second region W_R2. The second heater 72 may be disposed more outwardly (e.g., farther from a center of the chamber 10) than the first heater 71. The heater 70 may further include a third heater 73 and a fourth heater 74. The third heater 73 may be disposed more outwardly (e.g., farther from a center of the chamber 10) than the second heater 72, and the fourth heater 74 may be disposed more outwardly (e.g., farther from a center of the chamber 10) than the third heater 73. For example, the first heater 71, the second heater 72, the third heater 73, and the fourth heater 74 may be disposed at position corresponding to (e.g., vertically overlapping) the first region W_R1, the second region W_R2, the third region W_R3, and the fourth region W_R4, respectively. For example, each of the first to fourth heaters 71, 72, 73 and 74 may be a constituent of the heater 70. In certain embodiments, the substrate processing apparatus 1 may include a plurality of heaters 70 in which case each of the first to fourth heaters 71, 72, 73 and 74 may be one of the plurality of heaters 70.

The second heater 72 may adjust the temperature of the first heater 71 independently. For example, the first heater 71 and the second heater 72 may be separated from each other. For example, the first to fourth heaters 71, 72, 73 and 74 may be thermally insulated from each other. The temperature set by the first heater 71 may be lower than the temperature set by the second heater 72 to maintain the temperature throughout the substrate W uniformly. Therefore, etching gas and radicals of a lower temperature may be supplied to the first region W_R1, and etching gas and radicals of a higher temperature may be supplied to the second region W_R2 such that the process uniformity for the substrate W may be improved. For example, the temperature uniformity throughout the substrate W may be improved in the process.

The gas flow path GP may be connected to the first heater 71 and the second heater 72. For example, a first gas flow path GP1, through which a gas is heated by the first heater 71 and supplied to the processing region R2, and a second gas flow path GP2, through which a gas is heated by the second heater 72 and supplied to the processing region R2. For example, the gas flow path GP may include the first gas flow path GP1 and the second gas flow path GP2 (e.g., as sub-gas flow paths of the gas flow path GP). In certain embodiments, the substrate processing apparatus 1 may include a plurality of gas flow paths GP such that each of the first gas flow path GP1 and the second gas flow path GP2 is one of the plurality of gas flow paths GP. The shower head 30 may include the first gas injection unit (the first part) 311 disposed downstream of the first heater 71 and the second gas injection unit (the second part) 312 disposed downstream of the second heater 72. The first gas flow path GP1 may be formed to pass through the first heater 71 and the first gas injection unit 311, and the second gas flow path GP2 may be formed to pass through the second heater 72 and the second gas injection unit 312.

The partition structure 32 may be disposed between the first heater 71 and the second heater 72. The partition structure 32 may be disposed between the first gas injection unit 311 and the second gas injection unit 312. For example, the first gas flow path GP1 and the second gas flow path GP2 may be separated by the partition structure 32. For example, the partition structure 32 may be placed between the first gas flow path GP1 and the second gas flow path GP2.

The radical flow path RP may pass through the interior of the partition structure 32. In some example embodiments, the partition structure 32 may include two rings spaced apart, e.g., in a radial direction, by a predetermined gap. In certain embodiments, the partition structure 32 may include two or more concentric rings, e.g., in a plan view. The radical flow path RP may be formed in the predetermined gap of the partition structure 32 and the radicals may move therethrough. However, this is only an example, and the partition structure 32 may have a different structure. For example, the radical flow path RP may be arranged in a place spaced apart from the partition structure 32 in certain embodiments.

The blocker 40 may selectively allow the radicals present in the plasma to pass through the blocker 40 to the processing region R2. A plurality of holes may be formed in the blocker 40 to allow the radicals to pass therethrough. The blocker 40 may block ions present in the plasma from moving to the processing region R2. For example, the blocker 40 may block the movement of hydrogen ions (H⁺) and allow the movement of hydrogen radicals (H*).

In some example embodiments, the blocker 40 may capture the ions present in the plasma. The blocker 40 may include a conductive material to capture the ions. For example, the blocker 40 may be formed by applying alumina coating on stainless steel (SUS) or may be formed of alumina. However, the materials or configuration of the blocker 40 are not limited to the above description.

The gas supply 50 may include an etching gas line 51 for supplying an etching gas to the heater 70 and a carrier gas line 52 for supplying a carrier gas to the heater 70. For example, the etching gas may be a fluorine (F)-based gas, but is not limited thereto. The etching gas may be changed to an appropriate type or an appropriate type of etching gas may be selected according to the characteristics of the target film to be etched. The carrier gas may be an inert gas such as argon (Ar), but is not limited thereto.

The etching gas line 51 and the carrier gas line 52 may be connected to the heater 70. The temperature of the etching gas supplied from the etching gas line 51 and the temperature of the carrier gas supplied from the carrier gas line 52 may be adjusted by the heater 70. The etching gas line 51 may be connected to the gas flow path GP. In addition, the carrier gas line 52 may be connected to the gas flow path GP such that the carrier gas is mixed with the etching gas supplied to the gas flow path GP through the etching gas line 51. The etching gas and the carrier gas may be mixed in the gas flow path GP.

The etching gas line 51 may include a first etching gas line 511 for supplying the etching gas to the first heater 71 and a second etching gas line 512 for supplying the etching gas to the second heater 72. For example, each of the first etching gas line 511 and the second etching gas line 512 may be a corresponding part of the etching gas line 51. In certain embodiments, the substrate processing apparatus 1 may include a plurality of etching gas lines 51, and each of the first etching gas line 511 and the second etching gas line 512 may be a corresponding one of the plurality of etching gas lines 51. The carrier gas line 52 may include a first carrier gas line 521 for supplying the carrier gas to the first heater 71 and a second carrier gas line 522 for supplying the carrier gas to the second heater 72. For example, each of the first carrier gas line 521 and the second carrier gas line 522 may be a corresponding part of the carrier gas line 52. In certain embodiments, the substrate processing apparatus 1 may include a plurality of carrier gas lines 52, and each of the first carrier gas line 521 and the second carrier gas line 522 may be a corresponding one of the plurality of carrier gas lines 52. The first etching gas line 511 and the first carrier gas line 521 may be connected to the first gas flow path GP1. The etching gas and the carrier gas may be mixed in the first gas flow path GP1. The second etching gas line 512 and the second carrier gas line 522 may be connected to the second gas flow path GP2. The etching gas and the carrier gas may be mixed in the second gas flow path GP2. The gas present in the first gas flow path GP1 and the gas present in the second gas flow path GP2 may have different temperatures from each other. For example, the temperature of the gas present in the second gas flow path GP2 may be higher than the temperature of the gas present in the first gas flow path GP1.

The radical flow path RP may include a first radical flow path RP1 formed/passing between the first heater 71 and the second heater 72, a second radical flow path RP2 formed/passing between the second heater 72 and the third heater 73, and a third radical flow path RP3 formed/passing between the third heater 73 and the fourth heater 74. For example, the first radical flow path RP1, the second radical flow path RP2, and the third radical flow path RP3 may be sub-radical flow paths of the radical flow path RP. In certain embodiments, the substrate processing apparagus1 may include a plurality of radical flow paths RP in which case each of the first radical flow path RP1, the second radical flow path RP2, and the third radical flow path RP3 may be a radical flow path of the plurality of radical flow paths RP. The temperature of the radicals passing through the first radical flow path RP1 may be adjusted by the first heater 71 and the second heater 72. The temperature of the radicals passing through the second radical flow path RP2 may be adjusted by the second heater 72 and the third heater 73. The temperature of the radicals passing through the third radical flow path RP3 may be adjusted by the third heater 73 and the fourth heater 74. Because temperatures of the first to fourth heaters 71, 72, 73 and 74 are independently controlled, the temperatures of the radicals passing through the respective first to third radical flow paths RP1, RP2, and RP3 may be controlled by the first to fourth heaters 71, 72, 73 and 74 and may be different from each other. For example, the temperature of the radicals passing through the third radical flow path RP3 may be the highest, and the temperature of the radicals passing through the first radical flow path RP1 may be the lowest.

The substrate support 20 may include a heater channel 23 and a cooling channel 24 for adjusting the temperature of the substrate W. The substrate support 20 may adjust the temperature of the substrate W by heating or cooling the substrate support 20 and/or the substrate W. The heater channel 23 and the cooling channel 24 may be provided inside the substrate support 20.

The substrate support 20 may include a plurality of heater channels 23 arranged in a concentric pattern with respect to the drive shaft 22, e.g., in a plan view. The plurality of heater channels 23 may be arranged/configured in a concentric shape. The plurality of heater channels 23 may include a first heater channel 23a adjacent to the center of the substrate W, a second heater channel 23b disposed more outwardly than the first heater channel 23a, a third heater channel 23c disposed more outwardly than the second heater channel 23b, and a fourth heater channel 23d disposed more outwardly than the third heater channel 23c. Each of the first to fourth heater channels 23a, 23b, 23c, and 23d may independently adjust the temperature. For example, the first to fourth heater channels 23a, 23b, 23c, and 23d may be controlled to have different temperatures from each other. For example, the first to fourth heater channels 23a, 23b, 23c, and 23d may be disposed to correspond to (e.g., vertically overlap) the first to fourth regions W_R1, W_R2, W_R3, and W_R4 of the substrate W.

A coolant may flow through the cooling channel 24 to cool the substrate W. For example, the coolant may include water, ethylene glycol, silicone oil, liquid Teflon, a mixture of water and glycol, etc. The cooling channel 24 may have a concentric or helical pipe structure around the drive shaft 22. In some example embodiments, a cooling channel 20b may receive the coolant from the drive shaft 22. By the control unit (not illustrated), the flow rate and temperature of the coolant flowing into the cooling channel 20b may be adjusted.

As such, the substrate processing apparatus 1 according to some example embodiments may adjust the temperature of the substrate W on both surfaces of the substrate W. For example, the heater 70 may adjust the temperatures of the etching gas and the radicals from above the substrate W to adjust the temperature of each region of the substrate W, and the heater channel 23 and/or the cooling channel 24 may adjust the temperature of each region of the substrate W from below the substrate W. By ensuring temperature uniformity for each region of the substrate W as described above, deformation such as warpage of the substrate W may be prevented and the efficiency of the process may be improved.

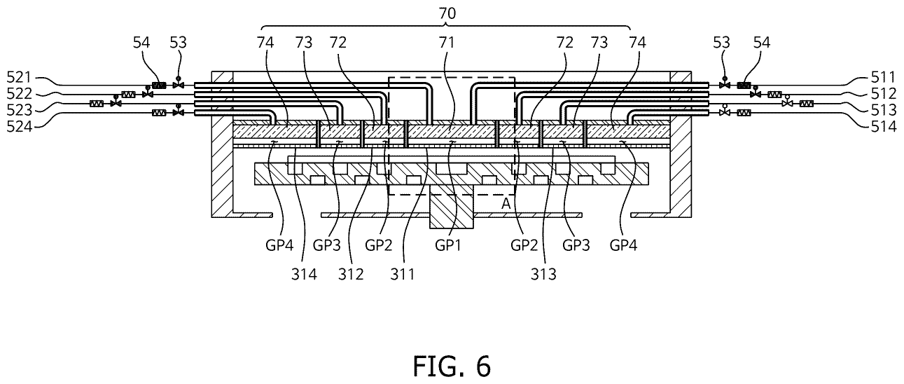

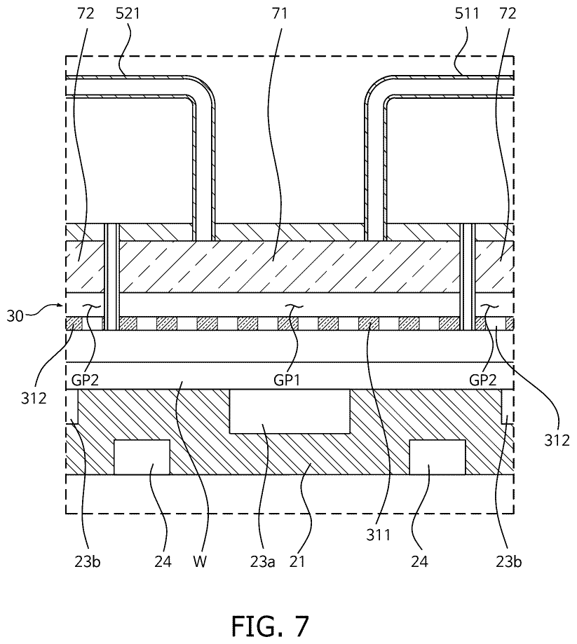

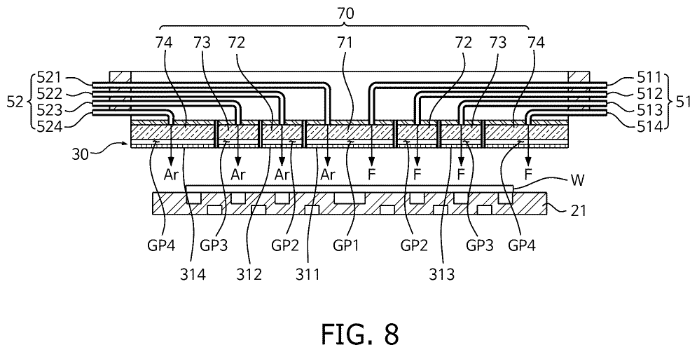

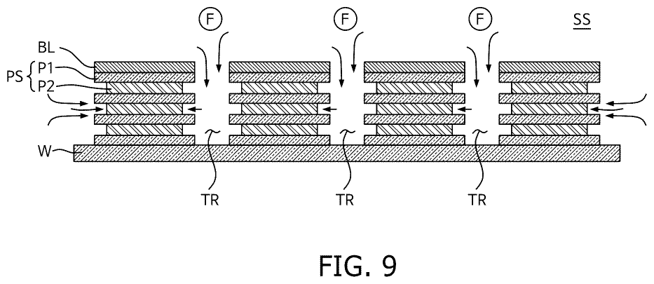

FIG. 6 is a cross-sectional view illustrating a partial configuration of the substrate processing apparatus of FIG. 5. FIG. 7 is an enlarged view of the region A of FIG. 6. FIG. 8 is a diagram provided to explain the etching process in the substrate processing apparatus according to some example embodiments. FIG. 9 is a cross-sectional view of a semiconductor structure manufactured using the substrate processing apparatus according to some example embodiments.

Referring to FIGS. 6 to 8, the etching process may be performed in the processing region R2 inside the chamber 10.

The shower head 30 may supply the carrier gas and the etching gas toward the substrate W. For example, the carrier gas may be argon (Ar) and the etching gas may be fluorine (F₂).

The shower head 30 may supply the carrier gas and the etching gas through each of the first gas flow path GP1 and the second gas flow path GP2. The gas flowing along the first gas flow path GP1 and the gas flowing along the second gas flow path GP2 may flow separately from each other. The temperature of the gas flowing along the first gas flow path GP1 may be adjusted by the first heater 71, and the temperature of the gas flowing along the second gas flow path GP2 may be adjusted by the second heater 72. For example, the gas inside the first gas flow path GP1 and the gas inside the second gas flow path GP2 may have different temperatures from each other. For example, the temperature of the gas inside the first gas flow path GP1 may be lower than the temperature of the gas inside the second gas flow path GP2. For convenience of description, the example embodiments have been described above with reference to the first gas flow path GP1 and the second gas flow path GP2 only, but the same description may be applicable to a third gas flow path GP3 and a fourth gas flow path GP4.

The etching gas line 51 may include the first etching gas line 511 for supplying the etching gas to the first gas flow path GP1 and the second etching gas line 512 for supplying the etching gas to the second gas flow path GP2. The first etching gas line 511 and the first carrier gas line 521 may be connected to the first gas flow path GP1, and the second etching gas line 512 and the second carrier gas line 522 may be connected to the second gas flow path GP2. A valve 53 and a gas line heater 54 may be provided on each of the etching gas line 51 and the carrier gas line 52. For example, the valve 53 and the gas line heater 54 may be disposed on each of the first to fourth etching gas lines 511, 512, 513, and 514, and on the first to fourth carrier gas lines 521, 522, 523, and 524. With this configuration, the temperature and/or flow rate of the etching gas or the carrier gas may be adjusted in advance before the etching gas or the carrier gas is supplied to the shower head 30. The valve 53 and the gas line heater 54 may be provided for each gas line such that the temperature and/or flow rate of the gas flowing through each of the first to fourth gas flow paths GP1, GP2, GP3, and GP4 may be individually adjusted. For example, the temperature and/or flow rate of the gas supplied to each region of the substrate W may be adjusted/controlled independently from the other regions of the substrate W.

The first heater channel 23a and the second heater channel 23b inside the substrate support 20 may adjust the temperature independently of each other. The first heater channel 23a may adjust the temperature of the first region of the substrate W, and the second heater channel 23b may adjust the temperature of the second region W_R2 of the substrate W. For example, the set temperature of the first heater channel 23a may be lower than the set temperature of the second heater channel 23b. For convenience of description, the example embodiments have been described above with reference to the first heater channel 23a and the second heater channel 23b only, but the same description may be applicable to the third heater channel 23c and the fourth heater channel 23d.

The substrate support 20 may be rotatably driven during the process. The substrate support 20 may be rotated with respect to the drive shaft 22 such that the temperature uniformity of the substrate W may be improved. For example, the heated etching gas or carrier gas may be evenly injected onto the substrate W.

In some example embodiments, a temperature sensor (not illustrated) may be provided inside the substrate support 20. The temperature sensor may measure the temperature of each region of the substrate W and transmit the measured temperature to the control unit (not illustrated). The control unit may control the set temperature of the heater adjacent to each region of the substrate W. In certain embodiments, a plurality of temperature sensors may be provided in the substrate support 20 to measure temperatures of the plurality of regions of the substrate W, respectively.

The temperatures of the etching gas and the carrier gas may be adjusted by the heater 70 in the shower head 30. The etching gas and the carrier gas may be heated by the heater 70. The heated etching gas may reach the substrate W and react with the semiconductor pattern to etch the layer to be etched. For example, the fluorine gas may selectively etch a silicon germanium (SiGe) layer of the substrate W. However, this is only an example, and other types of etching gases may also be used to etch semiconductor patterns formed of different materials.

Referring to FIG. 9, semiconductor patterns may be formed on the substrate W to form a semiconductor structure SS. The semiconductor structure SS may include a pattern structure PS formed on the substrate W. The pattern structure PS may have a structure in which a first pattern P1 and a second pattern P2 are alternately stacked. For convenience of description, the first pattern P1 may be a silicon (Si) layer, and the second pattern P2 may be a silicon germanium (SiGe) layer. For example, the pattern structure PS may be a stacked pattern in which a plurality of semiconductor patterns are stacked, and the semiconductor structure SS may be formed of a plurality of pattern structurers PS spaced apart from each other. In the semiconductor device, the first pattern P1 may be a channel of a transistor formed in later processes, and the second pattern P2 may be a gate of the transistor. A barrier layer BL may be formed on the pattern structure PS to prevent the first pattern P1 (e.g., silicon (Si) layer) from being removed/damaged. For example, the barrier layer BL may include a silicon oxide layer, etc.

A trench TR for separating the semiconductor devices may be formed in the semiconductor structure SS. The trench TR may separate the pattern structure PS at predetermined intervals. The etching gas supplied from the shower head may be introduced into the trench TR to selectively etch the second pattern P2. For example, silicon germanium (SiGe) may react with fluorine (F₂) gas and decomposed into SiF₄ gas and GeF₄ gas. However, when a difference in bonding energy between the first pattern P1 and the second pattern P2 is small, the first pattern P1 may be etched together, resulting in the loss of silicon atoms. When the first pattern P1 is etched together, the surface of the first pattern P1 may be roughened, and impurities may remain on the roughened surface. As described above, there may occur the roughness or crystalline disorder in the etching process, which may cause the mobility of the carrier to be reduced. For example, the roughened surface of the channel pattern and the remaining impurities may degrade the electrical performance of the semiconductor device.

The substrate processing apparatus according to some example embodiments may perform the etching process and the annealing process in a single chamber such that the roughness or crystalline disorder, etc. of a channel pattern formed in the semiconductor structure SS formed on the substrate W may be reduced. The annealing process performed in the substrate processing apparatus according to some example embodiments will be described.

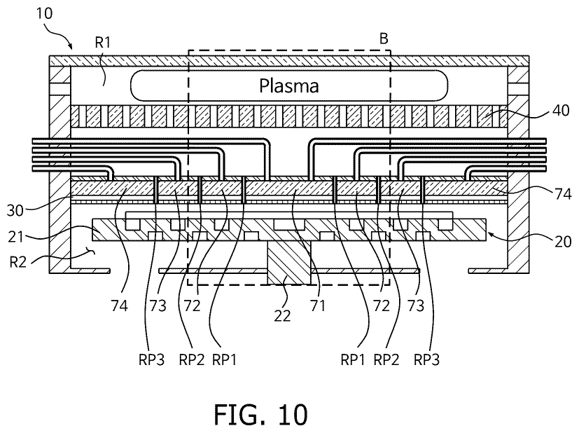

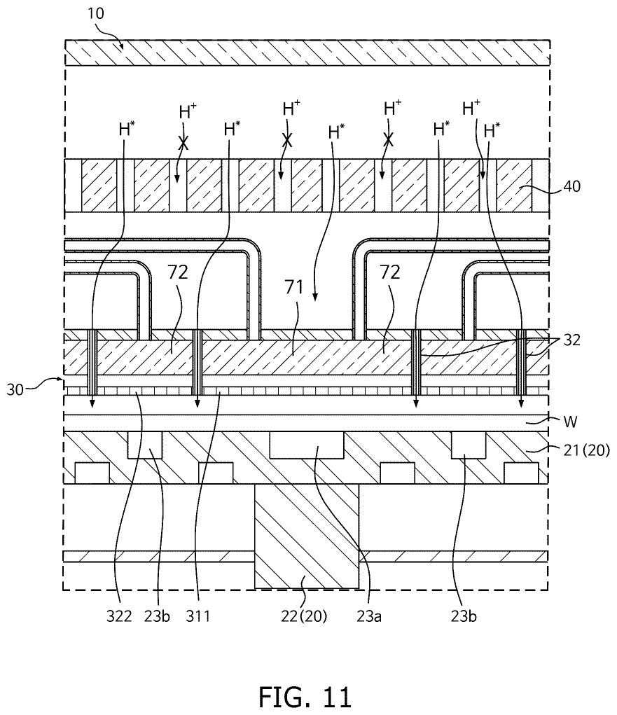

FIG. 10 is a diagram provided to explain the annealing process in the substrate processing apparatus according to some example embodiments. FIG. 11 is an enlarged cross-sectional view of the region B of the substrate processing apparatus of FIG. 10.

Referring to FIGS. 10 and 11, the substrate processing apparatus according to some example embodiments may perform the annealing process following the etching process on the semiconductor structure SS. For example, the annealing process may be performed according to the hydrogen plasma anneal (HPA) method.

The hydrogen gas H₂ supplied to the plasma region R1 may be dissociated into hydrogen ions H⁺, hydrogen radicals H*, etc. The hydrogen radicals H* present in the plasma of the plasma region R1 may pass through the blocker 40 and be supplied to the processing region R2. The hydrogen ions H⁺ present in the plasma may be blocked by the blocker 40 and thus may not be moved to the processing region R2. The blocker 40 may prevent the hydrogen ions H⁺ from being moved to the processing region R2 such that ion bombardment that may occur on the substrate W may be prevented.

The hydrogen radicals H* moved to the processing region R2 may be supplied to the substrate W through the radical flow path RP formed in the shower head 30. For example, radical flow paths RP may be formed in the shower head 30, and some other radical flow paths RP may be formed in the heater 70 such that the radical flow paths RP in the shower head 30 may be connected to and vertically aligned with the radical flow paths RP of the heater 70, respectively. The radical flow path RP may be formed between a plurality of heaters 70 such that the hydrogen radicals H* may be heated by the plurality of heaters 70. For example, for temperature uniformity for each region of the substrate W, each of the plurality of heaters 70 may be independently adjusted to control the temperature of the hydrogen radicals (H*). For example, the temperature of the hydrogen radicals H* passing through the first radical flow path RP1 may be lower than the temperature of the hydrogen radicals H* passing through the second radical flow path RP2. In this way, the temperature of the hydrogen radicals (H*) in the shower head 30 may be adjusted/controlled.

The first heater channel 23a and the second heater channel 23b inside the substrate support 20 may adjust the temperature of the substrate W. For example, the temperature of the pattern where the hydrogen radicals H* react may increase. The plurality of heaters 70 or the heater channels 23a and 23b inside the substrate support 20 may adjust the temperature of the hydrogen radicals (H*) to approximately 450° C. to 550° C. to induce the movement of silicon atoms. The hydrogen radicals H* supplied toward the substrate W may be combined with silicon atoms of the first pattern formed on the substrate W to facilitate the movement of the silicon atoms. The surface energy of the silicon atoms may be reduced by the combination of silicon atoms and hydrogen radicals. Additionally, the substrate support 20 may be rotatably driven during the annealing process. The substrate support 20 and the substrate W may rotate with respect to the drive shaft 22 such that the temperature uniformity of the substrate W may be improved. For example, the heated hydrogen radicals may be evenly injected onto the substrate W. For this reason, roughness, crystalline disorder, etc. generated in the etching process may be considerably removed/cured such that constituent atoms of the substrate W arrange orderly and surfaces of the substrate W are smoothed.

In the substrate processing apparatus according to some example embodiments, both the etching process and the annealing process may be performed while the substrate W is supported on a substrate support 20 and positioned in a single chamber such that the substrate W may not be exposed to the air between the etching process and the annealing process. For example, an oxide film, etc. may not be formed on the surface of the substrate W between the etching process and the annealing process, and loss of silicon may be prevented while removing the oxide film formed on the substrate W when the substrate W is exposed to the air between the etching process and the annealing process. In addition, both high-temperature and low-temperature processes may be performed in a single chamber such that the efficiency of the semiconductor manufacturing process may be improved.

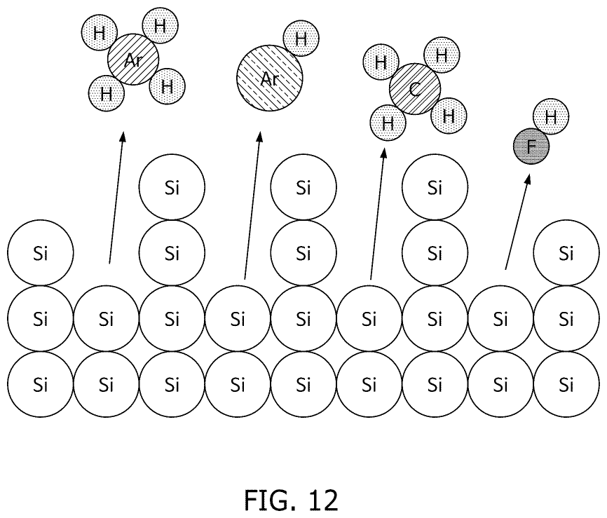

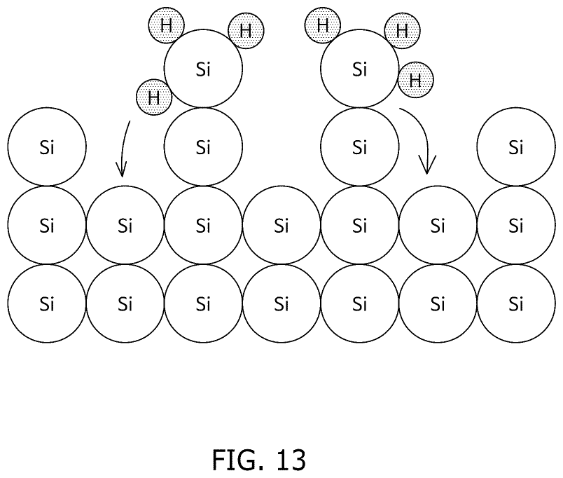

FIGS. 12 and 13 are conceptual diagrams illustrating a portion of the semiconductor structure of FIG. 9.

Referring to FIGS. 12 and 13, a reaction occurring on the surface of the semiconductor structure during the etching process and the annealing process performed using the substrate processing apparatus according to some example embodiments will be described.

Referring to FIG. 12, the first pattern of the semiconductor structure may include silicon atoms. The first pattern may be partially etched in the process of selectively etching the second pattern. As a result, the first pattern may have a rough surface.

Impurities such as nitrogen atoms (N), carbon atoms (C), fluorine atoms (F), etc. may remain on the roughened surface of the first pattern. When the impurities remain, the movement of the silicon atoms may be hindered. The hydrogen radicals may be combined with the impurities such as nitrogen atoms (N), carbon atoms (C), fluorine atoms (F), etc. and vaporize them into forms such as NH₄, CH₄, HF, etc. to remove the impurities. A space for the silicon atoms to move may be secured as the impurities are removed.

Referring to FIG. 13, the silicon atoms may be combined with hydrogen radicals to reduce binding energy of the silicon atoms positioned on the surface. The hydrogen radicals may be combined with the silicon atoms such that the binding energy of the silicon atoms on the surface may be reduced. For example, the silicon atoms and the hydrogen radicals may be combined to reduce the activation energy for the movement of silicon atoms. For example, the silicon atoms on the surface may be easily moved. Thus, the silicon atoms may move in a direction that reduces the surface energy, that is, to make the surface smoother.

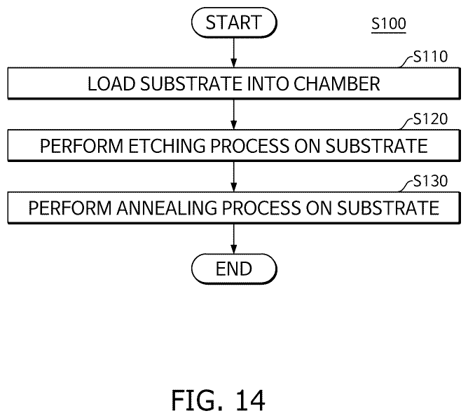

FIG. 14 is a flowchart illustrating a substrate processing method according to some example embodiments.

Referring to FIG. 14, a substrate processing method S100 according to some example embodiments may include a sequence of first to third operation S110 to S130.

Certain aspects may be implemented differently in certain embodiments. For example, the processes may be performed differently from the order described herein. For example, two processes described in succession/sequence in FIG. 14 may be performed substantially simultaneously or simultaneously, or may be performed in the opposite order to the order described in FIG. 14 in certain embodiments.

The substrate processing method S100 according to some example embodiments may include an operation S110 of loading the substrate into the chamber. The substrate may be seated on the substrate support inside the chamber. For example, the substrate may be seated on a substrate support 20 installed inside a chamber 10 of the substrate processing apparatus described with reference to FIGS. 1 to 11.

The substrate processing method S100 according to some example embodiments may include an operation S120 of performing the etching process on the substrate. For example, in the substrate processing apparatus described with reference to FIGS. 1 to 11, the etching gas provided from the gas supply 50 may be sprayed onto the substrate W in the processing region R2 through the shower head 30. Accordingly, the semiconductor structure formed on the substrate W may be etched to have appropriate semiconductor patterns. For example, after the silicon (Si) layer and the silicon germanium (SiGe) layer are alternately stacked, a trench may be formed to separate devices, and the silicon germanium layer may be selectively etched.

The substrate processing method S100 according to some example embodiments may include an operation S130 of performing the annealing process on the substrate. For example, in the substrate processing apparatus described with reference to FIGS. 1 to 11, the plasma gas supplied from the gas supply 50 to a plasma region S1 may be converted into plasma by the high-frequency power applied from the power supply 60. The plasma may include hydrogen ions (H⁺), hydrogen radicals (H*), etc. The blocker 40 disposed between the plasma region R1 and the processing region R2 in the chamber 10 may selectively allow the radicals present in the plasma to pass through the blocker 40 to the processing region R2. The shower head 30 may supply the radicals introduced from the plasma region R1 toward the substrate W. As the hydrogen plasma anneal (HPA) method is executed according to such a configuration of the substrate processing apparatus, the roughness formed on the surface of the silicon (Si) layer in the semiconductor structure formed on the substrate W may be alleviated.

Although the present disclosure has been described above by way of certain example embodiments and drawings, the inventive concept is not limited thereto, and it goes without saying that various changes and modifications can be made within the equivalent scope of the technical idea of the present disclosure and the claims to be described below by those of ordinary skill in the art. For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

1. A substrate processing apparatus, comprising:
a chamber including a plasma region and a processing region configured to process a substrate;
a gas supply configured to supply a plasma gas to the plasma region and supply an etching gas to the processing region;
a power supply configured to generate a plasma from the plasma gas;
a blocker disposed between the plasma region and the processing region and configured to selectively allow radicals in the plasma to pass from the plasma region to the processing region through the blocker;
a shower head including a gas flow path configured to supply the etching gas to the processing region and a radical flow path configured to supply the radicals to the processing region; and
a heater configured to adjust a temperature of the etching gas moving along the gas flow path or a temperature of the radicals moving along the radical flow path.

2. The substrate processing apparatus according to claim 1, wherein
the heater includes:
a first heater disposed in a central region of the heater; and
a second heater surrounding the first heater and configured such that a temperature of the second heater is adjusted independently of the first heater.

3. The substrate processing apparatus according to claim 2, wherein
the gas flow path is connected to each of the first heater and the second heater, and
the radical flow path is formed between the first heater and the second heater.

4. The substrate processing apparatus according to claim 3, wherein
the shower head further includes a first gas injection unit disposed downstream of the first heater and a second gas injection unit disposed downstream of the second heater, and
the gas flow path includes a first gas flow path formed to pass through the first heater and the first gas injection unit, and a second gas flow path formed to pass through the second heater and the second gas injection unit.

5. The substrate processing apparatus according to claim 4, wherein
the shower head further includes a partition separating the first gas flow path and the second gas flow path from each other, and
the radical flow path passes through an interior of the partition.

6. The substrate processing apparatus according to claim 4, wherein
the gas supply includes an etching gas line configured to supply the etching gas to each of the first heater and the second heater, and
the etching gas line is connected to the gas flow path.

7. The substrate processing apparatus according to claim 6, wherein
the gas supply further includes a carrier gas line configured to supply a carrier gas to each of the first heater and the second heater, and
the carrier gas line is connected to the gas flow path and configured such that the carrier gas is mixed with the etching gas supplied to the gas flow path through the etching gas line.

8. The substrate processing apparatus according to claim 7, wherein the gas supply further includes a valve and a gas line heater disposed on each of the etching gas line and the carrier gas line.

9. The substrate processing apparatus according to claim 2, wherein the substrate processing apparatus is configured such that a temperature set by the first heater is lower than a temperature set by the second heater.

10. The substrate processing apparatus according to claim 2, wherein
the heater further includes a third heater surrounding the second heater.

11. The substrate processing apparatus according to claim 1, wherein the blocker includes a conductive material.

12. The substrate processing apparatus according to claim 1, further comprising a substrate support disposed in the processing region and configured to support the substrate,
wherein the substrate support includes a pedestal and a drive shaft and the pedestal is configured to rotate about the drive shaft perpendicular to the pedestal.

13. The substrate processing apparatus according to claim 12, wherein the substrate support includes a heater channel and a cooling channel configured to adjust a temperature of the substrate.

14. The substrate processing apparatus according to claim 1, wherein the plasma region is formed above the blocker, and the processing region is disposed below the blocker.

15. A substrate processing apparatus, comprising:
a chamber including a plasma region configured such that a plasma including ions and radicals is formed in the plasma region, and a processing region configured such that a substrate is processed in the processing region;
a blocker disposed between the plasma region and the processing region, the blocker configured to allow the radicals to pass from the plasma region to the processing region through the blocker and block the ions;
a shower head including a first gas flow path configured to supply an etching gas to a first region of the substrate, a second gas flow path configured to supply an etching gas to a second region surrounding the first region of the substrate, and a radical flow path configured to supply the radicals passed through the blocker to the substrate;
a first heater connected to the first gas flow path; and
a second heater connected to the second gas flow path,
wherein the first heater and the second heater are separated from each other with the radical flow path therebetween.

16. The substrate processing apparatus according to claim 15, wherein the radical flow path is formed inside a partition that separates the first heater and the second heater.

17. The substrate processing apparatus according to claim 15, further comprising
a first etching gas line configured to supply the etching gas to the first heater and a second etching gas line configured to supply the etching gas to the second heater,
wherein the first heater and the second heater are configured to be operated independently of each other.

18. The substrate processing apparatus according to claim 15, wherein the ions are hydrogen ions, and the radicals are hydrogen radicals.

19. A substrate processing apparatus, comprising:
a chamber including a plasma region configured such that a plasma including hydrogen ions and hydrogen radicals is formed in the plasma region, and a processing region configured to process a substrate;
a gas supply configured to supply a hydrogen gas to the plasma region and supply an etching gas to the processing region;
a power supply disposed above the chamber and generating a plasma from the hydrogen gas;
a blocker disposed inside the chamber to separate the plasma region and the processing region, wherein the blocker allows the hydrogen radicals to pass through to the processing region and blocks the hydrogen ions;
a substrate support configured to support the substrate in the processing region and including a heater channel and a cooling channel therein, wherein the substrate support is rotatably drivable;
a shower head including a first gas flow path configured to supply an etching gas to a first region of the substrate, a second gas flow path configured to supply the etching gas to a second region surrounding the first region of the substrate, and a radical flow path configured to supply the hydrogen radicals passed through the blocker to the substrate;
a first heater connected to the first gas flow path; and
a second heater connected to the second gas flow path and surrounding the first heater,
wherein the radical flow path is formed between the first heater and the second heater, and
the first heater and the second heater are configured to be operated independently of each other and configured such that a temperature set by the first heater is lower than a temperature set by the second heater.

20. The substrate processing apparatus according to claim 19, wherein
the gas supply includes:
a first etching gas line and a second etching gas line configured to supply the etching gas to the first heater and the second heater, respectively; and
a first carrier gas line and a second carrier gas line configured to supply a carrier gas to the first heater and the second heater, respectively, and
the first etching gas line and the first carrier gas line are connected to the first gas flow path, and the second etching gas line and the second carrier gas line are connected to the second gas flow path.
